(19) United States
(12) Patent Application Publication
(10) Pub. No.: US 2020/0066367 A1
(43) Pub. Date: Feb. 27, 2020

(54) MEMORY DEVICE CONTROLLER

(71) Applicant: International Business Machines Corporation, Armonk, NY (US)

(72) Inventors: Anil B. Lingambudi, Bangalore (IN); Diyanesh B. Chinnakkonda Vidyapoornachary, Bangalore (IN); Edgar R. Cordero, Round Rock, TX (US); Adam J. McPadden, Underhill, VT (US)

(21) Appl. No.: 16/108,206

(22) Filed: Aug. 22, 2018

(51) Int. Cl. G11C 29/44; G11C 29/38; G11C 29/36; G11C 29/52; G06F 11/14

(52) U.S. Cl. CPC G11C 29/44; G11C 29/38; G11C 29/36; G11C 2029/1208; G06F 11/1441; G11C 2029/3602; G11C 29/52

(57) ABSTRACT

In one example implementation according to aspects of the present disclosure, a system is provided that includes a host processing system and a memory device communicatively coupled to the host processing system. The memory device includes a memory device controller, a volatile memory module, and a non-volatile memory module. The memory device controller performs a method including writing a data pattern to the non-volatile memory module, reading the data pattern from the non-volatile memory module, comparing the data pattern from the non-volatile memory module to an expected data pattern, and, based at least in part on determining that the data pattern from the non-volatile memory module matches the expected data pattern, loading system data stored in the volatile memory module to the non-volatile memory module when the host processing system experiences a power loss.

### BACKGROUND

The present invention generally relates to processing systems, and more specifically, to a memory device controller.

Memory is used to store information in a processing system. Types of memory can include volatile memory, which requires power to maintain the stored information, and non-volatile memory, which can retain the stored information even without power. Some processing systems use both volatile and non-volatile memory to store information. Non-volatile memory can be particularly useful to store information when the processing system loses power, which can be caused, for example, by a planned power outage (e.g., a system reboot) and/or an unplanned power outage (e.g., loss of battery power, loss of grid power, etc.).

### SUMMARY

Embodiments of the present invention are directed to a system including a host processing system and a memory device communicatively coupled to the host processing system. The memory device includes a memory device controller, a volatile memory module, and a non-volatile memory module. The memory device controller performs a method including writing a data pattern to the non-volatile memory module, reading the data pattern from the non-volatile memory module, comparing the data pattern from the non-volatile memory module to an expected data pattern, and, based at least in part on determining that the data pattern from the non-volatile memory module matches the expected data pattern, loading system data stored in the volatile memory module to the non-volatile memory module when the host processing system experiences a power loss.

Embodiments of the present invention are directed to a computer-implemented method for testing a non-volatile memory module of a memory device communicatively coupleable to a host processing system, the memory device including the non-volatile memory module, a volatile memory module, and a memory device controller. A non-limiting example of the computer-implemented method includes writing, by the memory device controller, a data pattern to the non-volatile memory module; periodically performing, by the memory device controller, a read-compare function; and based at least in part on determining that the data pattern from the non-volatile memory module matches an expected data pattern, loading, by the memory device controller, system data stored in the volatile memory module to the non-volatile memory module when the host processing system experiences a power loss.

Embodiments of the present invention are directed to a memory device communicatively coupled to a host processing system, the memory device including a memory device controller, a volatile memory module, and a non-volatile memory module. The memory device controller performs a method including writing, by the memory device controller, a data pattern to the non-volatile memory module. The method further includes reading, by the memory device controller, the data pattern from the non-volatile memory module. The method further includes comparing, by the memory device controller, the data pattern from the non-volatile memory module to an expected data pattern. The method further includes based at least in part on determining that the data pattern from the non-volatile memory module matches the expected data pattern, loading, by the memory device controller, system data stored in the volatile memory module to the non-volatile memory module when the host processing system experiences a power loss.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a block diagram of an embodiment of a processing system for implementing the techniques described herein;

FIG. 2 depicts a memory device having a memory device controller, a non-volatile memory, and a volatile memory according to one or more embodiments described herein;

FIG. 3 depicts a flow diagram of a method for performing periodic testing of a non-volatile memory module of a memory device according to one or more embodiments described herein; and

FIG. 4 depicts a flow diagram of a method for performing periodic testing of a non-volatile memory module of a memory device according to one or more embodiments described herein.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

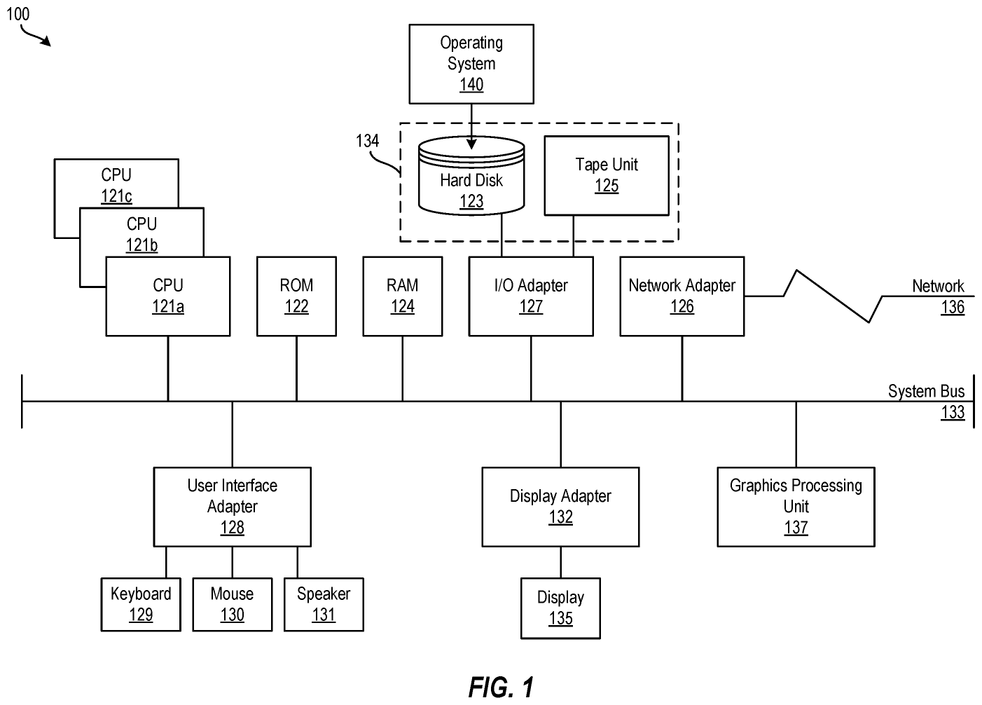

It is understood that the present disclosure is capable of being implemented in conjunction with any other type of computing environment now known or later developed. For example, FIG. 1 depicts a block diagram of a processing system 100 for implementing the techniques described herein. In examples, processing system 100 has one or more central processing units (processors) 121a, 121b, 121c, etc. (collectively or generically referred to as processor(s) 121 and/or as processing device(s)). In aspects of the present disclosure, each processor 121 can include a reduced instruction set computer (RISC) microprocessor. Processors 121 are coupled to system memory (e.g., random access memory (RAM) 124) and various other components via a system bus 133. Read only memory (ROM) 122 is coupled to system bus 133 and may include a basic input/output system (BIOS), which controls certain basic functions of processing system 100.

Further depicted are an input/output (I/O) adapter 127 and a network adapter 126 coupled to system bus 133. I/O adapter 127 may be a small computer system interface (SCSI) adapter that communicates with a hard disk 123 and/or a tape storage drive 125 or any other similar component. I/O adapter 127, hard disk 123, and tape storage device 125 are collectively referred to herein as mass storage 134. Operating system 140 for execution on processing system 100 may be stored in mass storage 134. The network adapter 126 interconnects system bus 133 with an outside network 136 enabling processing system 100 to communicate with other such systems.

A display (e.g., a display monitor) 135 is connected to system bus 133 by display adaptor 132, which may include a graphics adapter to improve the performance of graphics intensive applications and a video controller. In one aspect of the present disclosure, adapters 126, 127, and/or 232 may be connected to one or more I/O busses that are connected to system bus 133 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 133 via user interface adapter 128 and display adapter 132. A keyboard 129, mouse 130, and speaker 131 may be interconnected to system bus 133 via user interface adapter 128, which may include, for example, a Super I/O chip integrating multiple device adapters into a single integrated circuit.

In some aspects of the present disclosure, processing system 100 includes a graphics processing unit 137. Graphics processing unit 137 is a specialized electronic circuit designed to manipulate and alter memory to accelerate the creation of images in a frame buffer intended for output to a display. In general, graphics processing unit 137 is very efficient at manipulating computer graphics and image processing, and has a highly parallel structure that makes it more effective than general-purpose CPUs for algorithms where processing of large blocks of data is done in parallel.

Thus, as configured herein, processing system 100 includes processing capability in the form of processors 121, storage capability including system memory (e.g., RAM 124), and mass storage 134, input means such as keyboard 129 and mouse 130, and output capability including speaker 131 and display 135. In some aspects of the present disclosure, a portion of system memory (e.g., RAM 124) and mass storage 134 collectively store an operating system such as the AIX® operating system from IBM Corporation to coordinate the functions of the various components shown in processing system 100.

Turning now to an overview of technologies that are more specifically relevant to aspects of the invention, memory is useful for storing information in a processing system. The term “memory” is used herein to refer to computer hardware integrated circuits that store information for use by a processing system (i.e., a computer). When a planned or unplanned power outage occurs to a processing system, it can be desirable to store information in a non-volatile memory to preserve the information and make it available to the processing system again once power is restored.

Conventional processing systems use volatile memory as a main system memory for storing information used during operation of the processing system. However, non-conventional processing systems may utilize hybrid memory devices that include both volatile and non-volatile memory modules. For example, a non-volatile dual in-line memory module with nand memory (NVDIMM-N) is a type of memory device that utilizes both a volatile memory module and a non-volatile memory module. This enables the processing system to benefit from the information persistence of a non-volatile memory without the cost of using exclusively non-volatile memory in place of volatile memory. This improves the functioning of processing systems by improving information retention when a processing system loses power. One example of a technique for achieving non-volatility is to copy information from a volatile memory module of the memory device to a non-volatile memory module of the memory device invisibly to the processing system, even in the case that the processing system's power fails.

Turning now to an overview of the aspects of the invention, one or more embodiments of the invention address the above-described shortcomings of the prior art by performing periodic testing of a non-volatile memory module of a memory device. Memory devices, such as NVDIMM-N, are a complex composition of electronics which need appropriate strategies to ensure high field quality due to the newness of the technology and the complex implementation required between hardware and firmware. During memory device design, testing, and validation cycles, extensive testing is performed to identify failures within the non-volatile memory module of the memory device. However, such testing is not typically performed post-implementation of the memory device. It is common for the memory device to be used heavily by the processing system, but it is also common for the processing system to experiences losses in electricity only infrequently (e.g., once a year). As a result, the non-volatile memory module of the memory device may go unused for extended periods of time. As is the case with integrated circuit technology, the non-volatile memory module may change over time due to latent defects, electromigration, or other factors, which may negatively affect the non-volatile memory module's ability to reliability save data in the field.

The above-described aspects of the invention address the shortcomings of the prior art by performing periodic testing of a non-volatile memory module of a memory device. The present techniques ensure that the non-volatile memory module of the memory device (e.g., a NVDIMM-N) are used periodically to ensure optimal performance of the memory device. To do this, the memory module includes a memory device controller that writes a data pattern to the non-volatile memory module, reads the data pattern from the non-volatile memory, compares the data pattern from the non-volatile memory to an expected data pattern (i.e., the data pattern that was initially written to the non-volatile memory module), and then loads system data stored in the volatile memory to the non-volatile memory when the host processing system experiences a power loss based on determining that the data pattern from the non-volatile memory matches the expected data pattern. If the match is not confirmed, the present techniques can take mitigation steps, such as avoiding storing data into cells of the non-volatile memory that are determined to have errors, saving to another non-volatile memory, alerting a technician to change the memory device, etc. The present techniques provide technical solutions that improve processing systems by ensuring that the non-volatile memory module on a memory device is ready and able to receive copies of data from a volatile memory module when the processing system experiences a power loss or other similar event.

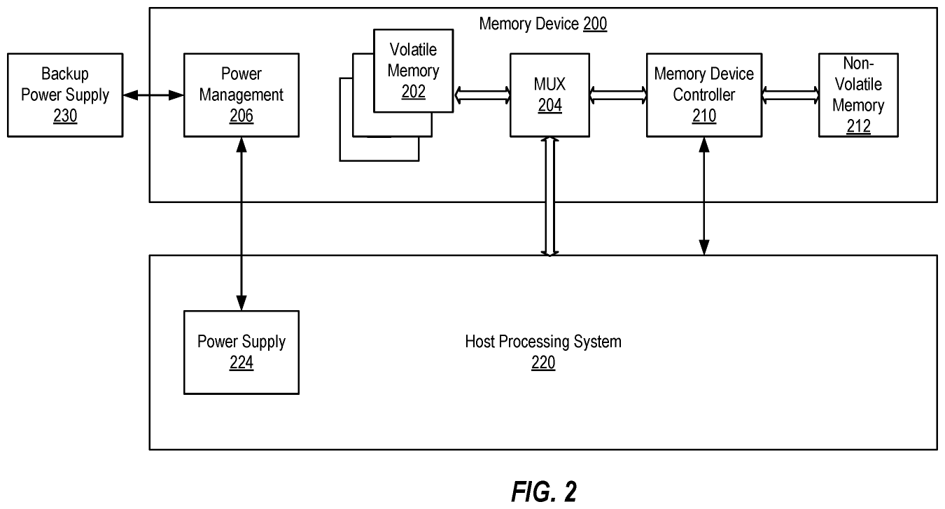

Turning now to a more detailed description of aspects of the present invention, FIG. 2 depicts a memory device having a memory device controller 210, a volatile memory module 202, and a non-volatile memory module 212 according to one or more embodiments described herein. The memory device controller 210 performs periodic testing of the non-volatile memory module 212.

The memory device 200 is communicatively coupled to a host processing system 220. For example, the memory device 200 can include pins (not shown) to physically connect to a socket or port (also not shown) on the host processing system 220. In one example, the memory device 200 includes 288 pins although other configurations are possible and within the scope of the present disclosure. The non-volatile memory module 212 can be a flash memory, such as NAND flash memory, and the volatile memory module 202 can be synchronous dynamic random access memory (SDRAM), although other types of volatile and non-volatile memory can be used.

According to one or more embodiments described herein, the host processing system 220 supplies power from the power supply 224 to the memory device 200, and the memory device can also receive power from a backup power supply 230, for example for providing power when the host processing system 220 ceases to provide power. For example, if the host processing system 220 experiences a planned or unplanned power cycle or power outage, the host processing system 220 stops providing power to the memory device 200. In such cases, the backup power supply 230 supplies power to the memory device 200. A power management module 206 on the memory device 200 monitors the power supply 224 of the host processing system 220 and switches to the backup power supply 230 when the host processing system 220 ceases to supply power to the memory device 200.

The host processing system 220 sends data to and receives data from the memory device 200 as depicted in FIG. 2. The memory device 200 receives data from the host processing system 220 at a multiplexer (MUX) 204 that cause the data to be routed to the volatile memory module 202 or the non-volatile memory module 212 (via the memory device controller 210).

In most cases, the host processing system 220 sends data to the memory device 200, and the data are stored in the volatile memory module 202. However, in some cases, such as when the host processing system 220 loses power, data is moved from the volatile memory module 202 to the non-volatile memory module 212 by the memory device controller 210. This enables the data to be preserved in the non-volatile memory module 212 during the power loss and restored to the volatile memory module 202 once power is restored (e.g., after a reboot of the host processing system 220).

When the host processing system 220 powers up, once the data is restored from the non-volatile memory module 212 to the volatile memory module 202, the present techniques provide for programming/writing a data pattern to the non-volatile memory module 212. The data pattern can be a pseudorandom binary sequence (PRBS) or another suitable target topography. Once the data pattern is written to the non-volatile memory module 212, the memory device controller 210 periodically reads the data pattern from the non-volatile memory module 212 and compares the data pattern from the non-volatile memory module 212 to an expected data pattern (i.e., the data pattern that was written to the non-volatile memory module 212). The expected data pattern can be stored, for example, in the volatile memory module 202. In other words, the memory device controller 210 performs a read-compare function on the data in the non-volatile memory module 212. According to one or more embodiments described herein, the memory device controller 210 performs a comparison between a checksum of the data pattern when initially written to the non-volatile memory module 212 versus a current checksum calculated when the non-volatile memory module 212 is periodically checked. If the checksums do not match, the non-volatile memory module 212 may have one or more errors.

The memory device controller 210 can track failing cell addresses of cells that contain data that does not match the data that are expected to be within the cell based on the read-compare function. Since most processing system do experience some sort of power cycle, the memory device controller 210 can build a history of failing cells over time for the non-volatile memory module 212. If, over repeated power cycles, some cells start to fail earlier and earlier in time, this is a reliability concern and mitigating action can be taken. This enables the memory device controller 210 to build a predictive histogram and react when there is deviation.

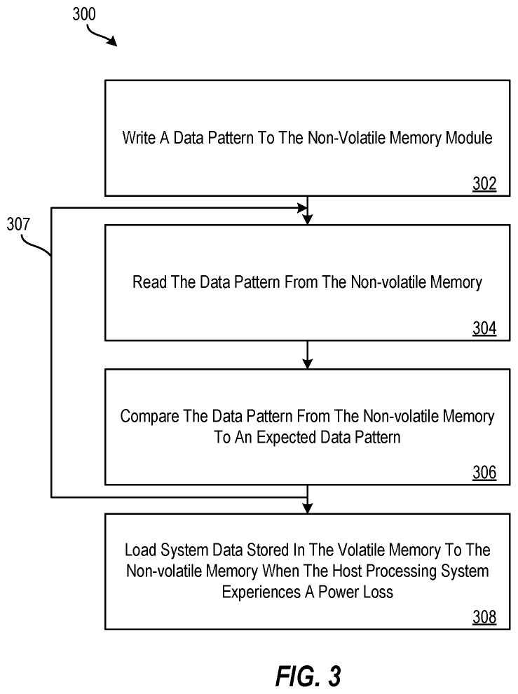

FIG. 3 depicts a flow diagram of a method 300 for performing periodic testing of a non-volatile memory module 212 of a memory device 200 according to one or more embodiments described herein.

At block 302, the memory device controller 210 writing a data pattern to the non-volatile memory module 212. The data pattern can be, for example, a pseudorandom binary string or another suitable data pattern.

At block 304, the memory device controller 210 reading the data pattern from the non-volatile memory module 212. At block 306, the memory device controller 210 comparing the data pattern from the non-volatile memory module 212 to an expected data pattern (which can be stored, for example, in the memory device controller 210 and/or in the volatile memory module 202).

The data can be read and compared periodically, such as every day, every week, every month, etc., as depicted in FIG. 3 by the loopback arrow 307. A frequency/period of the reading and the comparing can be based on various factors. For example, the frequency of the reading and the comparing being performed periodically is based on an expected lifetime of the non-volatile memory module 212. For example, as the non-volatile memory module 212 nears milestones of its expected lifetime (e.g., 50%, 75%, etc.), the frequency of the reading and comparing can increase.

In another example, the frequency of the reading and the comparing being performed periodically is based on a number of times that the host processing system 220 experiences a power loss. In another example, the frequency of the reading and the comparing being performed periodically is fixed and/or set by a user. In yet another example, the frequency of the reading and the comparing being performed periodically is based at least in part on a result of a prior reading and comparing. In this example, if prior reading and comparing indicate an increase in errors (or a number of errors in excess of a threshold), then the frequency of the reading and comparing can be increased. Conversely, if prior reading and comping do not indicate an increase in errors (or a number of errors is below a threshold), then the frequency of the reading and comparing can be decreased.

At block 308, the memory device controller 210, based at least in part on determining that the data pattern from the non-volatile memory module 212 matches the expected data pattern, loads system data stored in the volatile memory module 202 to the non-volatile memory module 212 when the host processing system 220 experiences a power loss. That is, when no errors are detected as a result of the reading and comparing, data is loaded from the volatile memory module 202 to the non-volatile memory module 212 when the host processing system 220 experiences a power loss. However, if the data do not match, this can indicate an error in the non-volatile memory module 212. In such cases, the memory device controller 210 can detect a bad cell within the non-volatile memory module 212, can determine a cell address associated with the bad cell, and can write the cell address to an error table. The memory device controller 210 can then avoid writing to bad cell addresses.

Additional processes also may be included, and it should be understood that the process depicted in FIG. 3 represents an illustration, and that other processes may be added or existing processes may be removed, modified, or rearranged without departing from the scope and spirit of the present disclosure.

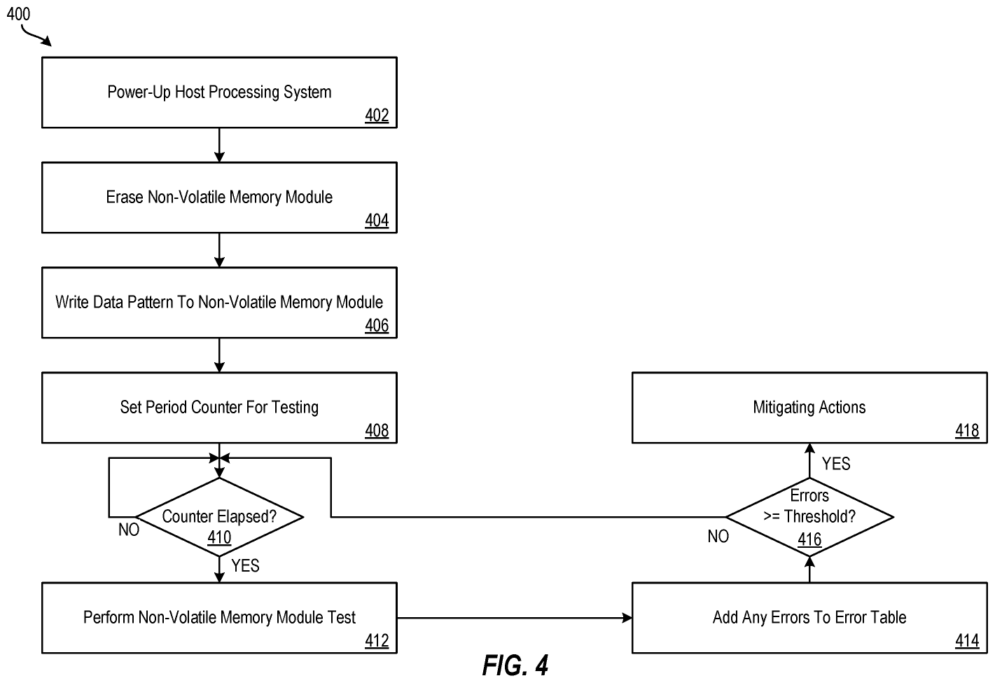

FIG. 4 depicts a flow diagram of a method for performing periodic testing of a non-volatile memory module 212 of a memory device 200 according to one or more embodiments described herein.

At block 402, the host processing system powers up, and at block 404, the memory device controller 210 erases the non-volatile memory module 212. At block 406, the memory device controller 210 writes a data pattern (e.g., a PRBS) to the non-volatile memory module 212.

At block 408, a period counter is set with a period that indicates how often testing of the non-volatile memory module 212 occurs (e.g., daily, weekly, etc.). At decision block 410 it is determined whether the counter set at block 408 has elapsed. If not, the method 400 waits until the counter has elapsed.

When it is determined at decision block 410 that the counter has elapsed, the memory device controller 210 performs a test on the non-volatile memory module 212 at block 412. For example, the memory device controller 210 performs a read-compare function to read the non-volatile memory module 212 and compare its current data to expected data. In this way, the memory device controller 210 can detect errors in the non-volatile memory module. In some examples, the testing includes performing a checksum compare between a checksum of data stored in the non-volatile memory module 212 and an expected checksum. Any errors found are added to an error table at block 414. Then it is determined, at decision block 416, whether a number of errors exceeds a threshold (which can be defined by the user or set automatically based on factors such as lifetime of the memory device, testing period, etc.).

If, at decision block 416, it is determined that the number of errors is no greater than the threshold, the method 400 returns to decision block 410, and periodic testing continues. However, if it is determined at decision block 416 that the number of errors is greater than or equal to the threshold, a mitigation action occurs at block 418. Examples of mitigation actions include replacing the memory device, avoiding using (by the host processing system) the memory device in favor of other memory devices associated with the host processing system 220, avoiding writing data to certain portions/cells of the non-volatile memory module 212, alerting a system administrator or technician of the failures, and the like.

Additional processes also may be included, and it should be understood that the process depicted in FIG. 4 represents an illustration, and that other processes may be added or existing processes may be removed, modified, or rearranged without departing from the scope and spirit of the present disclosure.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A system comprising:
a host processing system; and
a memory device communicatively coupled to the host processing system, the memory device comprising a memory device controller, a volatile memory module, and a non-volatile memory module, wherein the memory device controller performs a method comprising:
writing a data pattern to the non-volatile memory module,
reading the data pattern from the non-volatile memory module,
comparing the data pattern from the non-volatile memory module to an expected data pattern, and
based at least in part on determining that the data pattern from the non-volatile memory module matches the expected data pattern, loading system data stored in the volatile memory module to the non-volatile memory module when the host processing system experiences a power loss.

2. The system of claim 1, wherein the reading and the comparing are performed periodically.

3. The system of claim 2, wherein a frequency of the reading and the comparing being performed periodically is based on an expected lifetime of the non-volatile memory module.

4. The system of claim 2, wherein a frequency of the reading and the comparing being performed periodically is based on a number of times that the host processing system experiences a power loss.

5. The system of claim 2, wherein a frequency of the reading and the comparing being performed periodically is fixed.

6. The system of claim 2, wherein a frequency of the reading and the comparing being performed periodically is set by a user.

7. The system of claim 2, wherein a frequency of the reading and the comparing being performed periodically is based at least in part on a result of a prior reading and comparing.

8. The system of claim 1, wherein the method further comprises, based at least in part on determining that the data pattern from the non-volatile memory module does not match the expected data pattern, determining that a cell of the non-volatile memory module has failed, and storing a cell address of the cell that has failed to an error table.

9. The system of claim 8, wherein the method further comprises loading system data stored in the volatile memory module to at least one cell of a plurality of cells of the non-volatile memory module when the host processing system experiences a power loss without loading system data into any cells with cell addresses stored in the error table.

10. A computer-implemented method for testing a non-volatile memory module of a memory device communicatively coupleable to a host processing system, the memory device comprising the non-volatile memory module, a volatile memory module, and a memory device controller, the method comprising:
writing, by the memory device controller, a data pattern to the non-volatile memory module;
periodically performing, by the memory device controller, a read-compare function; and
based at least in part on determining that the data pattern from the non-volatile memory module matches an expected data pattern, loading, by the memory device controller, system data stored in the volatile memory module to the non-volatile memory module when the host processing system experiences a power loss.

11. The computer-implemented method of claim 10, further comprising, based at least in part on determining that the data pattern from the non-volatile memory module does not match the expected data pattern, determining that a cell of the non-volatile memory module has failed, and storing a cell address of the cell that has failed to an error table.

12. The computer-implemented method of claim 11, further comprising, loading system data stored in the volatile memory module to at least one cell of a plurality of cells of the non-volatile memory module when the host processing system experiences a power loss without loading system data into any cells with cell addresses stored in the error table.

13. The computer-implemented method of claim 10, wherein the read-compare function is based at least in part on the data pattern from the non-volatile memory module and an expected data pattern.

14. The computer-implemented method of claim 10, wherein the read-compare function is based at least in part on a checksum of the data pattern from the non-volatile memory module and an expected checksum.

15. A memory device communicatively coupled to a host processing system, the memory device comprising a memory device controller, a volatile memory module, and a non-volatile memory module, wherein the memory device controller performs a method comprising:
writing, by the memory device controller, a data pattern to the non-volatile memory module;
reading, by the memory device controller, the data pattern from the non-volatile memory module;
comparing, by the memory device controller, the data pattern from the non-volatile memory module to an expected data pattern; and
based at least in part on determining that the data pattern from the non-volatile memory module matches the expected data pattern, loading, by the memory device controller, system data stored in the volatile memory module to the non-volatile memory module when the host processing system experiences a power loss.

16. The memory device of claim 15, wherein the reading and the comparing are performed periodically.

17. The memory device of claim 16, wherein a frequency of the reading and the comparing being performed periodically is based on an expected lifetime of the non-volatile memory module.

18. The memory device of claim 16, wherein a frequency of the reading and the comparing being performed periodically is based on a number of times that the host processing system experiences a power loss.

19. The memory device of claim 16, wherein a frequency of the reading and the comparing being performed periodically is fixed.

20. The memory device of claim 16, wherein a frequency of the reading and the comparing being performed periodically is set by a user.
